(19) United States
(12) Patent Application Publication
(10) Pub. No.: US 2014/0163908 A1
(43) Pub. Date: Jun. 12, 2014

(54) ELECTRICAL DEVICE MONITORING APPARATUS, METHOD THEREOF AND SYSTEM

(71) Applicant: KABUSHIKI KAISHA TOSHIBA, MINATO-KU (JP)

(72) Inventor: KAZUTO KUBOTA, KAWASAKI-SHI (JP)

(73) Assignee: KABUSHIKI KAISHA TOSHIBA, MINATO-KU (JP)

(21) Appl. No.: 14/183,107

(22) Filed: Feb. 18, 2014

Related U.S. Application Data
(63) Continuation of application No. PCT/JP2013/058469, filed on Mar. 18, 2013.

(30) Foreign Application Priority Data
Mar. 21, 2012 (JP) 2012-064367

(51) Int. Cl. G01R 21/133

(52) U.S. Cl. CPC G01R 21/133
USPC 702/61

(57) ABSTRACT

In one embodiment, a calculator calculates power consumed by devices and a feature at a time interval on a current and/or a voltage of a power supplier, a generating unit calculates a difference between the power consumption at the starting time and each power consumption and a difference between the feature at the starting time and each feature, in a first period from the starting time, for each device, creates, for each combination of the devices, a set of learning data including power consumption differences of devices therein and a sum of feature differences of the devices therein, generates a model to estimate, as a function of a first variable indicating the sum of feature differences, second variables indicating power consumption differences of each device, a estimating unit estimates power consumption of each device based on the model and the feature, the feature being given to the first variable.

### CROSS REFERENCE TO RELATED APPLICATIONS

This application is a Continuation of International Application No. PCT/JP2013/058469, filed on Mar. 18, 2013, the entire contents of which is hereby incorporated by reference.

### FIELD

Embodiments described herein relate to an electrical device monitoring apparatus and a method thereof to estimate power consumption of an electrical device, and an electrical device monitoring system.

### BACKGROUND

There is known a technique of estimating ON/OFF and power consumption of an electrical device including an inverter device by measuring a current/voltage of a feeder service entrance in a power customer and calculating a feature (such as the intensity of harmonic). According to this technique, the ON/OFF state and power consumption of multiple devices can be estimated at one measurement point and a power measurement adaptor per device is not required. Therefore, it is expected to become common as a technique to realize visualization at a moderate price.

In the above technique, to estimate the ON/OFF and power consumption of devices, it is necessary to operate the devices for a certain period of time in a state where a power measurement adaptor is attached in advance. Subsequently, a set of the feature and power consumption of an individual device are measured to construct an estimation model. Therefore, in a case where a burden for model construction is large and the device varies across the ages, there is a possibility that the estimation model includes an error.

### BRIEF DESCRIPTION OF THE DRAWINGS

FIG. 1 illustrates an electrical device monitoring apparatus according to the present embodiment.

FIG. 2 illustrates a flow of a model generating phase.

FIG. 3 illustrates a flow of device operation and data collection processing.

FIG. 4 illustrates a flow of power consumption and feature collection processing.

FIG. 5 illustrates a flow of model data generation processing.

FIG. 6 illustrates a flow of power consumption estimation and visualization phase.

FIG. 7 is a view to explain an acquisition method of model creation data.

FIG. 8 illustrates a hardware configuration example of an electrical device monitoring apparatus.

FIG. 9 illustrates an electrical device monitoring system using data in multiple homes.

FIG. 10 is a view to explain another example of an acquisition method of model creation data.

FIG. 11 illustrates an example of a neural net model.

### DETAILED DESCRIPTION

According to one embodiment, there is provided an electrical device monitoring apparatus including: a measuring unit, a power consumption calculating unit, a power consumption storage, a feature calculating unit, a feature storage, a detecting unit, a model generating unit, and a power consumption estimating unit.

The measuring unit measures a current and a voltage of a power supplying unit that supplies power to a plurality of devices.

The power consumption calculating unit calculates power consumed by the devices at a time interval.

The power consumption storage accumulates a value of power consumption calculated by the power consumption calculating unit.

The feature calculating unit calculates a feature based on at least one of the current and the voltage at the time interval.

The feature storage accumulates the feature calculated by the feature calculating unit.

The detecting unit detects a starting time and an ending time of operating of each of the devices.

The model generating unit calculates calculate a power consumption difference between the power consumption at the starting time and each power consumption at the time interval, in a first period from the starting time, for each of the devices.

The model generating unit calculates a feature difference between the feature at the starting time and each feature at the time interval, in the first period from the starting time, for each of the devices.

The model generating unit creates, for each combination of the devices, a set of learning data each including power consumption differences of devices in the combination and a sum of feature differences of devices in the combination at the time interval.

The model generating unit generates a model to estimate, as a function of a first variable indicating the sum of feature differences, second variables indicating power consumption differences of the plurality of devices, based on all of each set of the learning data.

The power consumption estimating unit calculates the second variables of the model based on the feature calculated by the feature calculating unit, the feature being given to the first variable of the model and the second variables calculated representing power consumption of each of the plurality of devices.

In the following, with reference to the drawings, embodiments will be explained.

### First Embodiment

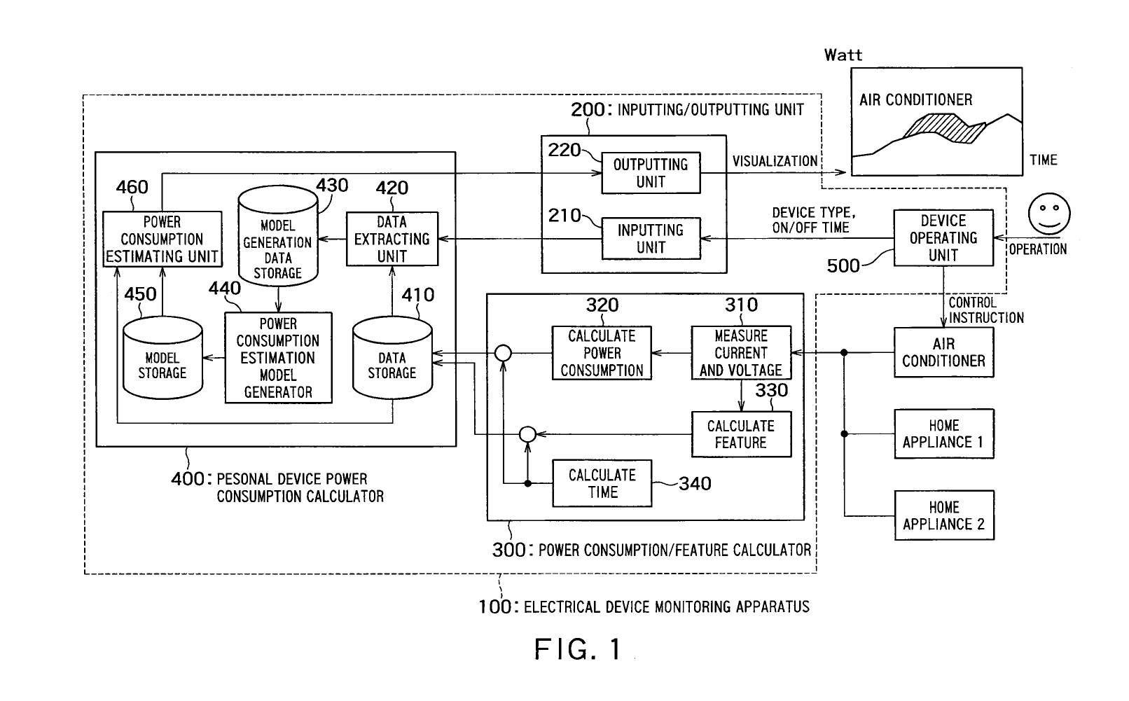

FIG. 1 illustrates a configuration of an electrical device monitoring apparatus 100 according to a first embodiment.

The electrical device monitoring apparatus 100 includes an inputting/outputting unit 200, a power consumption/feature calculator 300, an individual device power consumption calculator 400 and a device operating unit (detecting unit) 500.

The inputting/outputting unit 200 includes an inputting unit 210 and an outputting unit 220.

The power consumption/feature calculator 300 includes a current voltage measuring unit 310, a power consumption calculating unit 320, a feature calculating unit 330 and a timer (time calculating unit) 340.

The individual device power consumption calculator 400 includes a data storage (power consumption storage and feature storage) 410, a data extracting unit 420, a model generation data storage 430, a power consumption estimation model generator 440, a model storage 450 and a power consumption estimating unit 460.

The present apparatus includes a model generating phase of generating a model to estimate the power consumption of individual devices from power information in a home, and a power consumption estimation/visualization phase to actually estimate and visualize the power consumption using the generated model. After the model is generated in the model generating phase, these phases can operate in parallel (i.e. independently).

### (Model Generating Phase)

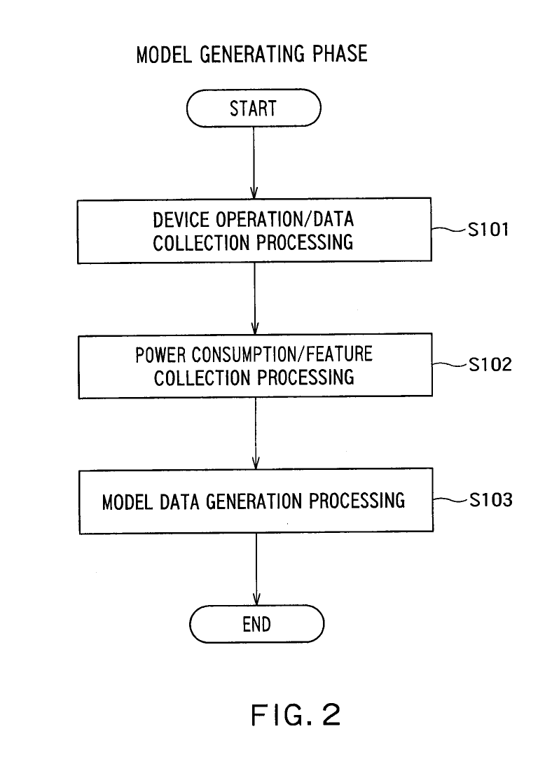

FIG. 2 illustrates a flow of processing in the model generating phase.

The model generating phase includes device operation/data collection processing (S101), power consumption/feature collection processing (S102) and model data generation processing (S103).

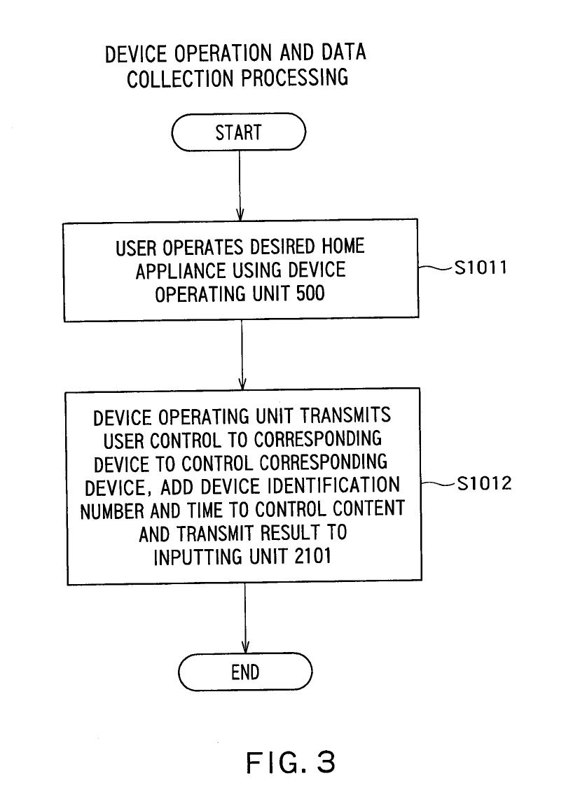

FIG. 3 illustrates a flow of the device operation/data collection processing in step S101.

The device operating unit 500 accepts a device operation from the user (S1011). For example, it accepts an ON/OFF operation of a device. Setting information such as the preset temperature of a device may be accepted. For example, the user can perform the device operation as behavior in normal daily life without taking care of an operation of the present apparatus.

In step S1012, the device operating unit 500 transmits a control instruction based on the user operation to a corresponding device. Also, it outputs identification data of the control (such as ON/OFF) to the inputting unit 210 where the identification data additionally includes the identification number (or individual identification number) of the device and the time the user operation was accepted. The household electrical appliance having received the control instruction performs an operation according to the control instruction.

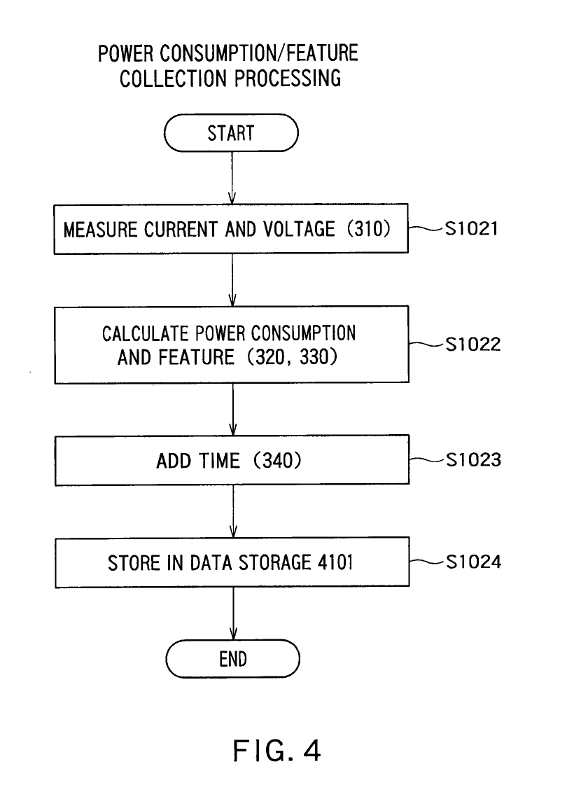

FIG. 4 illustrates a flow of the power consumption/feature collection processing in step S102.

In parallel to the device operation/data collection processing in step S101, the current voltage measuring unit 310 measures a current and voltage of a customer feeder part (i.e. power supplying unit) (S1021). The measurement is performed for, for example, 2 KHz/sec.

The power consumption calculating unit 320 calculates power consumption by integrating the current and the voltage. Also, the feature calculating unit 330 calculates a feature(s) from at least one of the current and the voltage (S1022).

For example, a frequency spectrum or phase is calculated by performing FFT (Fast Fourier Transform) on a measured current signal. Alternatively, a power factor is calculated from the voltage and the current.

The time in the timer (or time calculating unit) 340 is added to the value of the power consumption calculated in the power consumption calculating unit 320 (S1023) and data is transmitted to the data storage 410. Also, the time in the timer (or time calculating unit) 340 is added to the feature calculated in the feature calculating unit 330 (S1023) and data is transmitted to the data storage 410. The data storage 410 stores these items of data (S1024).

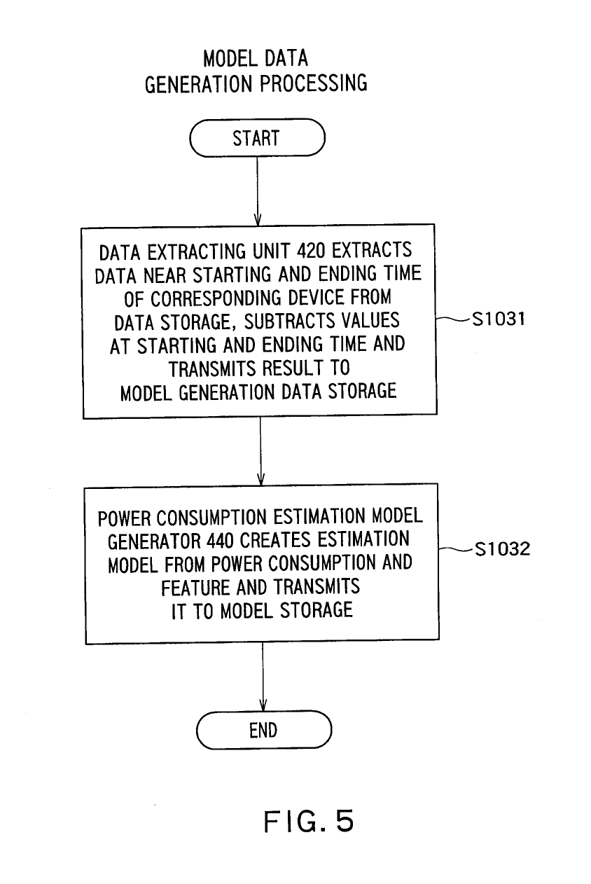

FIG. 5 illustrates a flow of the model data generation processing in step S103.

The data extracting unit 420 generates model generation data (i.e. first and second model generation data) to calculate a power consumption estimation model, using the individual identification number transmitted from the inputting unit 210 and the starting time and ending time of the device (S1031).

The generation of the model generation data is performed by using power consumption data and feature data stored in the data storage 410. Also, the power consumption data shows power consumption of the whole house (i.e. total power consumption of multiple devices in the home).

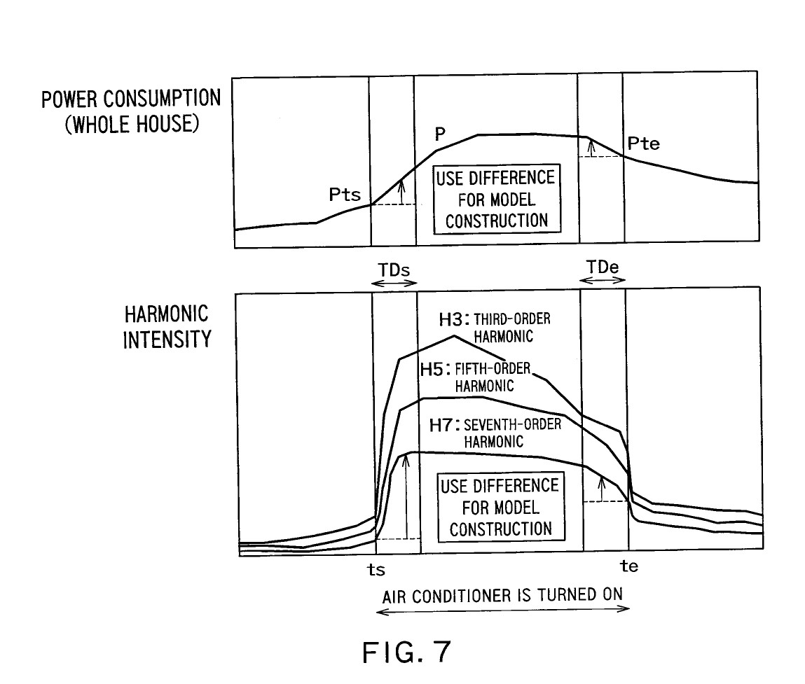

The upper part of FIG. 7 illustrates a case where first model generation data is generated from the power consumption data. There is shown a graph in which values of the power consumption are plotted and connected in a coordinate system formed with the time and the power consumption of the whole house. It illustrates a state where data used for model generation is extracted from there.

Power consumption Pts at the operation starting time of the device and power consumption Pte at the ending time are extracted from the data storage 410. The power consumption Pts is subtracted from power consumption P1 of each time (P1 is a vector) at intervals of a data generation time within time TDs from the starting time (i.e. first period), and thereby, a difference of power consumption is calculated at intervals of the data generation time. Here, it should be noted that the data generation time indicates a period to calculate a feature and differs from a measurement period of a current and a voltage. Also, the power consumption Pte is subtracted from power consumption P2 (P2 is a vector) of each time at intervals of the data generation time within time TDe before the ending time (i.e. second period), and thereby, a difference of power consumption is calculated at intervals of the data generation time. These items of difference data (power consumption difference and feature difference are stored in the model generation data storage 430 as first model generation data. Specifically, it is assumed that a period of TDs starting from the starting time is a short period, and, by regarding that other devices are not newly turned on during this period, it is possible to handle the difference between Pts and each P1 in the period of TDs as the power consumed by the device. Similarly, by regarding that the device is turned off at the ending time and other devices are not turned off during a period of TDe before the ending time, it is possible to handle the difference between Pte and each P1 in the period of TDe as the power consumed by the device.

The lower part of FIG. 7 illustrates a case where second model generation data is generated from feature data. There are shown graphs (i.e. third-order, fifth-order and seventh-order harmonic graphs) in which values of the feature are plotted and connected in a coordinate system formed with the time and the feature. It illustrates a state where data used for model estimation is extracted from these third-order, fifth-order and seventh-order harmonic graphs.

As feature data, a result of FFT is used. In the result of FFT, third-order harmonic data H3, fifth-order harmonic data H5 and seventh-order harmonic data H7 are shown. By extracting only values of third-order, fifth-order and seventh-order harmonics from the result of FFT and connecting these in the time direction, the graphs in the figure are acquired. That is, with respect to the power consumption data, FFT is performed at intervals of data generation time while moving a predetermined-width window from the start to the end of the power consumption data at a certain width (i.e. a length of data generation time) in the time direction. Further, by extracting only values of third-order, fifth-order and seventh-order harmonics and connecting these in the time direction, the graphs of third-order, fifth-order and seventh-order harmonics are acquired. These graphs are processed in the same way as in FIG. 7.

Specifically, in the third-order harmonic data, the intensity at the starting time is subtracted from the intensity of each time at intervals of data generation time within time TDs from the starting time, and a difference of the feature is calculated at intervals of data generation time. Also, the intensity at the ending time is subtracted from the intensity of each time at intervals of data generation time within time TDe before the ending time, and a difference of the feature is calculated at intervals of data generation time. These items of difference data (feature difference) are stored in the model generation data storage 430 as second model generation data. Also, regarding fifth-order and seventh-order harmonic data, second model generation data is created in the same way and stored in the model generation data storage 430.

The power consumption estimation model generator 440 generates a power consumption estimation model from the model generation data (i.e. first and second model generation data) per device stored in the model generation data storage 430. Regarding this, as described below, there are a method of generating the model for each device and a method of generating one item of model for a whole of the devices. In any cases, an existing technique is used.

For example, in related art, a model is learned by a neural net in which harmonic data is an input and power consumption is an output. In addition, there are suggested a method using RBF, support vector machine or LMC (Large Margin Classfier) and a method using GA.

The generated model is stored in the model storage 450. In the case where the power consumption estimation model is generated per device, identification information of the device is stored together.

Here, there is provided a method of generating the power consumption estimation model per device.

It is suggested that the length of TDs illustrated in FIG. 7 is 10 minutes and a data set (i.e. power consumption difference and feature difference) for 11 times is calculated at one-minute intervals. The one-minute corresponds to the data generation time. This data set is calculated from data collected at 2 KHz in a time period of one second before each time. In the following, an example of acquisition process of this data set (i.e. a set of learning data) is shown.

The following equation is an equation to generate a set of harmonics at certain time.

$${X}_{k} = {\sum }_{n = 0}^{N - 1} {x}_{n} {e}^{- i 2 π n / N} ( k = 1 , 2 , … , N - 1 )$$

The number of items of data is 2000 due to 2 KHz in one second. This is referred to as “xi.” Here, “i” indicates the i-th item in 2000 data. Also, “Xk” indicates a value after discrete Fourier transform. Also, “k” indicates a frequency component and k=150, k=250 and k=350 indicate the third-order harmonic, the fifth-order harmonic and the seventh-order harmonic. It is assumed that the order is referred to as “m” and an m-order harmonic is referred to as “Hm” (Hm is a vector) in a simple manner. That is, X150 corresponds to H3. Xk (K=150, 250 and 350) corresponding to the third order, fifth order and seventh order is a combination of harmonics at certain time. When the certain time is t1, a combination of harmonics at time t1 is represented by H3(t1), H5(t1) and H7(t1). Also, power consumption at certain time denotes an average of product of “i” and “v” in one second. This is represented by P(t1).

Here, it is assumed that the starting time of TDs is “ts.” In the case of acquiring data for ten minutes, a sequence of P(t), H3(t), H5(t) and H7(t) is acquired. Here, P(t) indicates power consumption at time t, where t∈{ts, ts+1, . . . , ts+10} is established. The order of harmonic may be increased according to sampling frequency.

Subsequently, calculations are performed for p(t)=P(t)−P(ts), h3(t)=H3(t)−H3(ts), h5(t)=H5(t)−H5(ts) and h7(t)=H7(t)−H7(ts). By this means, a data set (i.e. learning data) of p(t), h3(t), h5(t) and h7(t) for model generation is acquired.

In the interval of TDe in FIG. 7, by performing the same processing as in TDs, a data set (i.e. learning data) is acquired.

In the case of generating a power consumption estimation model for each device, a model outputting “p” as a function of |h3|, |h5| and |h7| is generated for each device. This can be constructed in, for example, a multiple regression model. That is, “a,” “b,” “c” and “d” may be determined such that the sum of squares of p−p′ (i.e. difference between p and p′) in the equation of p′=a*|h3|+b*|h5|+c*|h7|+d is minimum. The “*” indicates multiplication. Here, |h3|, |h5| and |h7| each correspond to a first variable indicating a feature difference and “p′” corresponds to a second variable indicating a power consumption difference.

Next, an explanation is given to the case of generating one power consumption estimation model for a whole of the devices.

This model corresponds to a model to estimate the power consumption of each device from the intensity of harmonic of power consumption “i” in the whole house. The intensity is not a difference but is a value itself of the graph in the lower part of FIG. 7.

Regarding an individual device “j,” it is assumed that data of a combination of power consumption and harmonic is pj, h3j, h5j and h7j. These indicate a power consumption difference and feature difference (i.e. harmonic intensity difference) which are acquired in the same way as when the above-described individual model is created.

It is assumed that all device combinations with respect to “j” are referred to as “J.” For example, in a case where the number of devices is three, J={(1), (1,2), (1,3), (2,3), (1,2,3)} is established.

Regarding each combination, data is randomly extracted one from the data set of each of devices included in the combination and, based on each extracted data of such devices, h3, h5 and h7 are added to each other. Also, “p” is used itself without being added and “p” of a device which is not included in the combination is set to 0. This data collection is described as “dx” and it is repeatedly created. Each created data collection is input in a data set D. When the number of repetitions is 1000, data collection of d1 to d1000 is input in D.

For example, in a case where the individual identifier of the device is 1 and 2, a data set {|h31+h32|, |h51+h52|, |h71+h72|, p1, p2, 0} is an example of dx, which includes: addition of h3, h5 and h7 with respect to randomly selected p1, h31, h51 and h71 and randomly selected p2, h32, h52 and h72; p1; p2; and power consumption p3 of a device which is not included in the combination, where the power consumption p3 is set to 0. This dx is represented as {hh3x, hh5x, hh7x, p1x, p2x, p3x}.

Using the data set D (i.e. learning data), a model to output p1, p2 and p3 as a function of hh3, hh5 and hh7 is generated as illustrated in FIG. 11. For example, a neural net model is generated. A generation method is well-known and therefore an explanation is omitted. Here, hh3, hh5 and hh7 each correspond to a first variable indicating a sum of feature differences, and p1, p2 and p3 each correspond to the second variable indicating the power consumption of each device.

Although a general flow of the model generating phase has been described above, repetition of this processing improves a model, resulting in a more accurate model.

### (Power Consumption Estimation/Visualization Phase)

The power consumption estimation/visualization phase estimates device power consumption using the model stored in the model storage 450.

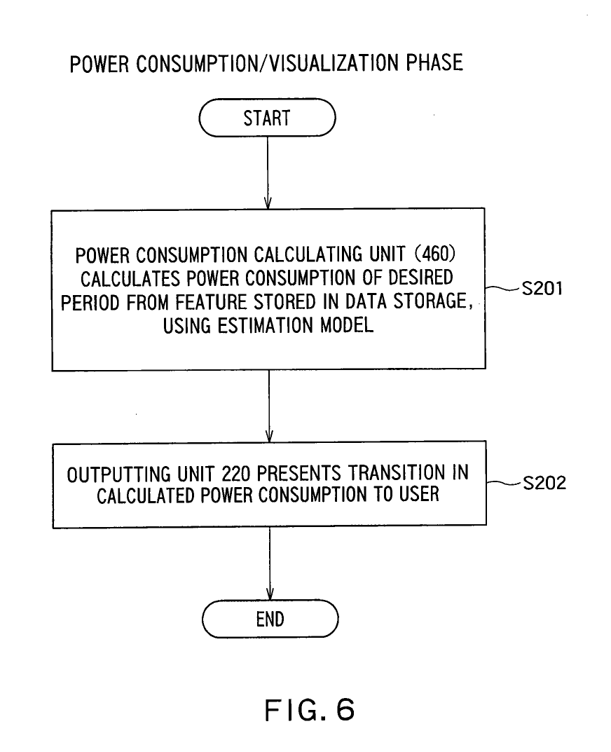

FIG. 6 illustrates a flow of the power consumption estimation/visualization phase.

The data storage 410 stores feature data calculated from home current and voltage information. The power consumption estimating unit 460 estimates the power consumption of each device from this feature. The estimation is performed in real time, for example, every one minute. The estimation method varies depending on whether to use the power consumption estimation model for each device (in the above example, multiple regression model) or use one power consumption estimation model for a whole of devices (i.e. the above neural net model).

In the case of using the power consumption estimation model for each device, it is premised where ON/OFF of each device is possible. The feature(s) in the whole house at time t to estimate power consumption is divided depending on operating devices.

For this purpose, for example, the feature pattern for each device (in the above example, intensity distribution of third-order, fifth-order and seventh-order harmonics) is learned in advance. For each device, a representative pattern (such as an average) of harmonic intensity distribution in a past operation period is learned. The pattern may be learned depending on an operation setting or state of the device (in the case of an air conditioner, a set temperature, an operation start period from the time when power-on is instructed to the time when the operation becomes stable, or a normal operation period).

Subsequently, the features (intensity of third-order, fifth-order and seventh-order harmonics) in the whole house at time t to estimate the power consumption are divided such that each divided features is the most closest to the corresponding pattern of each device, and each divided features are determined as the features of each device. By inputting the determined features of a target device among each device into the model of the target device (i.e. multiple regression model) as the first variables, power consumption of the target device is obtained as a value of the second variable being output of the model. Here, this is just an example and an arbitrary method can be used.

In the case of using one power consumption estimation model for a whole of the devices, the features (intensity of third-order, fifth-order and seventh-order harmonics in the whole house) at time t are given to a neural net model as the first variables. By this means, the power consumption of each device is acquired as second variables being output of the model. According to this, even in an environment in which ON/OFF measurement per device is not possible, it is easily possible to estimate the power consumption of the individual device.

The outputting unit 220 outputs the estimated power consumption so as to be visualized by the user. For example, it is displayed in a graph such that not only transition in the power consumption in a house but also the device-basis power consumption is identified. The upper right of FIG. 1 illustrates an example where only a power consumption of an air conditioner is displayed.

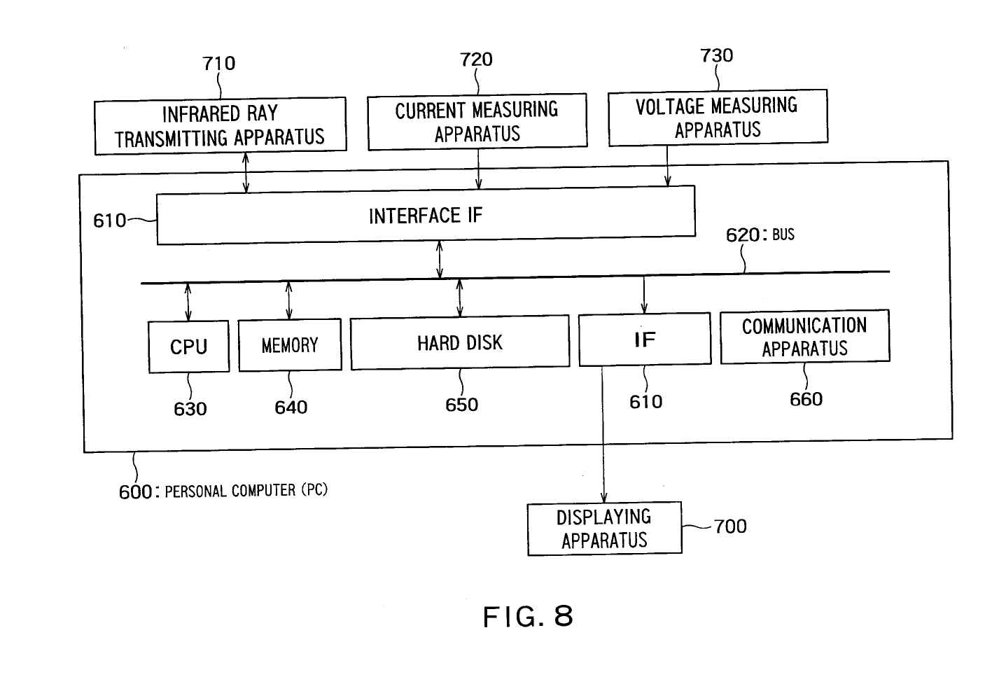

The electrical device monitoring apparatus illustrated in FIG. 1 is formed including a personal computer (PC) 600, an infrared ray transmitting apparatus 710, a current measuring apparatus 720, a voltage measuring apparatus 730 and a displaying apparatus 700, which are illustrated in FIG. 8. The infrared ray transmitting apparatus 710 is an example of a remote controller to operate a device by the user.

The voltage and current of a customer feeder are measured in the current measuring apparatus 720 and the voltage measuring apparatus 730. The measured values are subjected to AD conversion in an interface unit 610 and stored in a memory 640 or a hard disk 650 on a PC. The processing in the power consumption calculating unit 320 and the feature calculating unit 330 is performed by reading and executing a program stored in the memory 640 by a CPU 630. The calculation results in these calculating units are stored in the memory 640 or the hard disk 650. Each processing in the individual device power consumption calculator 400 is performed on the PC 600. Visualization information of the power consumption of an individual device for a liver is generated on the PC 600 and presented to the liver using the displaying apparatus 700.

Also, the present electrical device monitoring apparatus may be formed with multiple PCs. In a case where the power consumption/feature calculator 300 and the individual device power consumption calculator 400 are realized on different PCs, required data is exchanged using a communication apparatus 660 of the PCs.

As described above, according to the present embodiment, it is possible to easily or automatically construct a power consumption estimation model while the user lives. Since a power consumption measuring apparatus does not have to be attached to individual devices, it is possible to construct an estimation model at low cost, thereby realizing a technique of visualization at a low price with a low burden on customers.

### Second Embodiment

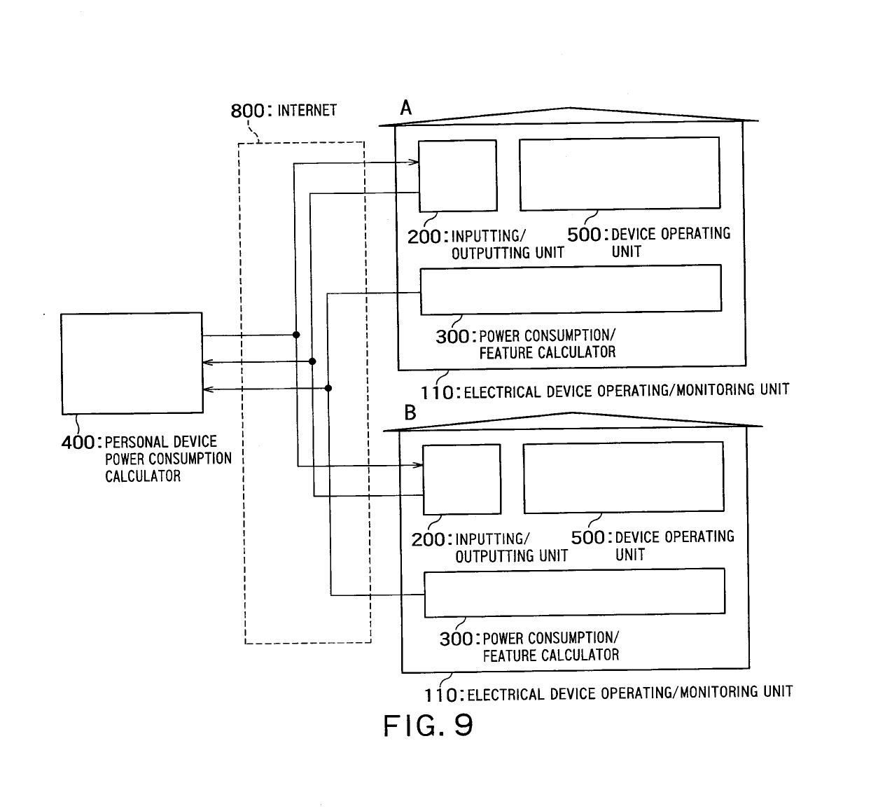

FIG. 9 illustrates a configuration of an electrical device monitoring apparatus according to the present embodiment. The present embodiment describes a method of generating the power consumption estimation model for each device from power consumption information and device information in multiple homes.

The individual device power consumption calculator 400 illustrated in FIG. 1 is commonly set in a remote server arranged on the Internet, for each home. Also, an electrical device operating/monitoring unit 110 including the inputting/outputting unit 200, the device operating unit 500 and the power consumption/feature calculator 300 is set for each home. FIG. 9 illustrates an example case where the number of homes is two. The individual device power consumption calculator 400 and the electrical device operating/monitoring unit 110 in each home are connected to each other via the Internet.

The power consumption estimation model is created as follows. Data is acquired in homes A and B in the same way as in the first embodiment and transmitted to the individual device power consumption calculator 400. Here, it is assumed that the same devices or devices of the same model number have the same characteristics, and the power consumption estimation model generator 440 (see FIG. 1) generates a model of the devices (i.e. common model) using the data from both homes. Regarding the devices for which the common model is generated, the power consumption estimation is performed using the common model. However, when data is sufficiently accumulated in each home, a model may be created for every home to perform the power consumption estimation using each model.

Also, even immediately after setting devices in which data is not collected yet, regarding the same device and devices of the same model number, it is possible to effectively perform power consumption estimation immediately after the setting, by a model created from data of a different home.

### Third Embodiment

The present embodiment shows another method of generating model generation data (i.e. the above-described first model generation data and second model generation data) to generate a power consumption estimation model.

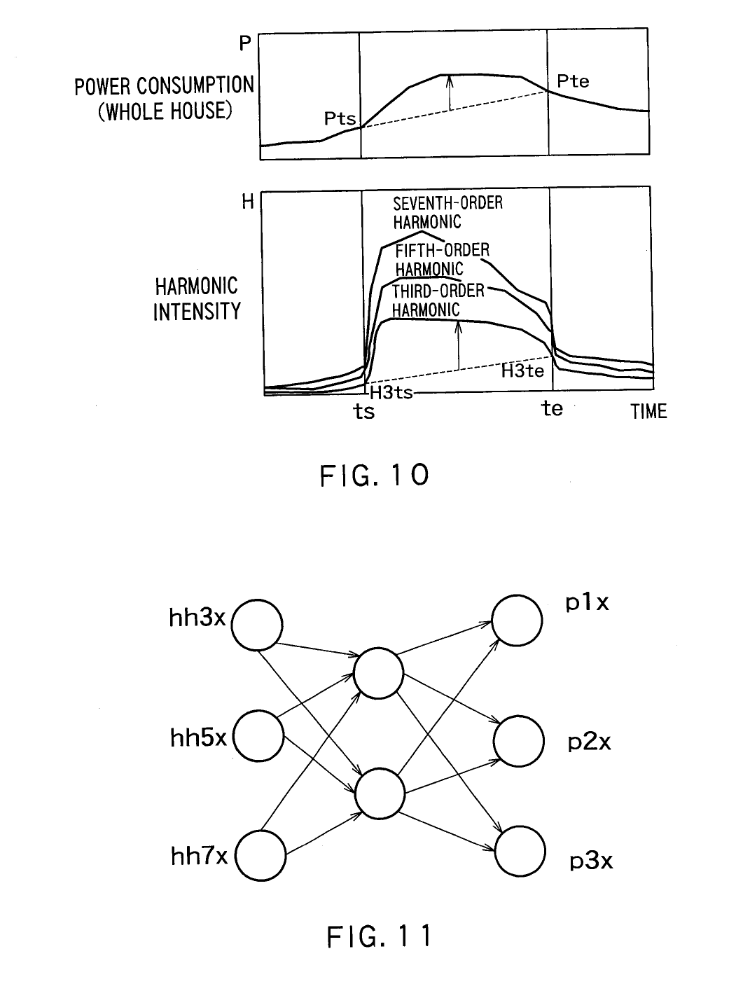

FIG. 10 illustrates power consumption (upper part of the figure) and features (lower part of the figure) acquired in a certain home.

The data extracting unit 420 extracts all data during a time period from the operation starting time of the device to the ending time.

At this time, regarding power consumption, the data extracting unit 420 draws a line segment to interpolate operation starting time is of the device to ending time te, as a base line. Subsequently, a value subtracting a value of the base line from power consumption in one home is regarded as power consumption of the device and acquired as first model generation data.

Regarding a feature, a base line is drawn in the same way. A value subtracting a value of the base line from the feature is regarded as a feature of the device and acquired as second model generation data.

In the first embodiment, as illustrated in FIG. 7, a difference from Pts at the starting time and a difference from PTe at the ending time are acquired as power consumption (i.e. first model generation data). Even in the first embodiment, a base line may be drawn in the same way as in the present embodiment, a value subtracting a value of the base line from the power consumption within the starting time period TDs and the ending period TDe may be regarded as power consumption of the device and acquired as first model generation data. The same applies to the feature.

As described above, according to the present embodiment, in the whole operation period of a device, it is possible to acquire power consumption and feature of the device in a simple manner.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An electrical device monitoring apparatus comprising:
a measuring unit configured to measure a current and a voltage of a power supplying unit that supplies power to a plurality of devices;
a power consumption calculating unit configured to calculate power consumed by the devices at a time interval;
a power consumption storage configured to accumulate a value of power consumption calculated by the power consumption calculating unit;
a feature calculating unit configured to calculate a feature based on at least one of the current and the voltage at the time interval;
a feature storage configured to accumulate the feature calculated by the feature calculating unit;
a detecting unit configured to detect a starting time and an ending time of operating of each of the devices;
a model generating unit configured to: calculate a power consumption difference between the power consumption at the starting time and each power consumption at the time interval, in a first period from the starting time, for each of the devices;
calculate a feature difference between the feature at the starting time and each feature at the time interval, in the first period from the starting time, for each of the devices;
create, for each combination of the devices, a set of learning data each including power consumption differences of devices in the combination and a sum of feature differences of devices in the combination at the time interval; and,
generate a model to estimate, as a function of a first variable indicating the sum of feature differences, second variables indicating power consumption differences of the plurality of devices, based on all of each set of the learning data; and
a power consumption estimating unit configured to calculate the second variables of the model based on the feature calculated by the feature calculating unit, the feature being given to the first variable of the model and the second variables calculated representing power consumption of each of the plurality of devices.

2. The apparatus according to claim 1, wherein the model generating unit further acquires a power consumption difference between the power consumption at the ending time and each power consumption at the time interval, in a second period before the ending time, for each of the devices, and further acquires a feature difference between the feature at the ending time and each feature at the time interval, in the second period before the ending time, for each of the devices.

3. The apparatus according to claim 1, wherein:
the model generating unit plots values of the power consumption in a coordinate system formed with time and power consumption, generates a base line connecting between a value of the power consumption at the starting time and a value of the power consumption at the ending time, and calculates the power consumption difference by subtracting a value of the base line from the power consumption at the time interval in the first period; and
the model generating unit plots each feature in a coordinate system formed with time and feature, generates a base line connecting between the feature at the starting time and the feature at the ending time, and calculates the feature difference by subtracting a value of the base line from the feature at the time interval in the first period.

4. The apparatus according to claim 3, wherein the model generating unit calculates the power consumption difference and the feature difference in an entire period from the starting time to the ending time.

5. The apparatus according to claim 1, wherein the feature calculating unit calculates a frequency spectrum by performing Fourier transform on the current or the voltage, as the feature.

6. An electrical device monitoring apparatus comprising:
a measuring unit configured to measure a current and a voltage of a power supplying unit that supplies power to a plurality of devices;
a power consumption calculating unit configured to calculate power consumed by the devices at a time interval;
a power consumption storage configured to accumulate a value of power consumption calculated by the power consumption calculating unit;
a feature calculating unit configured to calculate a feature based on at least one of the current and the voltage at the time interval;
a feature storage configured to accumulate the feature calculated by the feature calculating unit;
a detecting unit configured to detect a starting time and an ending time of operating of each of the devices;
a model generating unit configured to: calculate a power consumption difference between the power consumption at the starting time and each power consumption at the time interval, in a first period from the starting time, for each of the devices;
calculate a feature difference between the feature at the starting time and each feature at the time interval, in the first period from the starting time, for each of the devices;
generate, for each of the devices, a set of learning data each including the power consumption difference and the feature difference at the time interval; and,
generate, for each of the devices, a model to estimate, as a function of a first variable indicating the feature difference, a second variable indicating the power consumption difference, based on the set of learning data; and
a power consumption estimating unit configured to divide the feature calculated by the feature calculating unit among operating devices out of the devices to obtain a divided feature of each operating device, and calculates, for each operating device, the second variable of the model based on the divided feature, the divided feature being given to the first variable of the model and the second variable calculated representing power consumption of the operating device.

7. The electrical device monitoring apparatus according to claim 6, wherein the model generating unit further acquires a power consumption difference between the power consumption at the ending time and each power consumption at the time interval, in a second period before the ending time, for each of the devices, and further acquires a feature difference between the feature at the ending time and each feature at the time interval, in the second period before the ending time, for each of the devices.

8. The electrical device monitoring apparatus according to claim 6, wherein:
the model generating unit plots values of each power consumption in a coordinate system formed with time and power consumption, generates a base line connecting between a value of the power consumption at the starting time and a value of the power consumption at the ending time, and calculates the power consumption difference by subtracting a value of the base line from the power consumption at the time interval in the first period; and
the model generating unit plots each feature in a coordinate system formed with time and feature, generates a base line connecting the feature at the starting time to the feature at the ending time, and calculates the feature difference by subtracting a value of the base line from the feature at the time interval in the first period.

9. The electrical device monitoring apparatus according to claim 8, wherein the model generating unit calculates the power consumption difference and the feature difference in an entire period from the starting time to the ending time.

10. The electrical device monitoring apparatus according to claim 6, wherein the feature calculating unit calculates a frequency spectrum by performing Fourier transform on the current or the voltage, as the feature.

11. An electrical device monitoring system comprising:
a plurality of electrical apparatuses arranged in a plurality of homes in each of which a plurality of devices are arranged; and
a power consumption calculating apparatus connected to the electrical devices via a network, wherein:
the electrical apparatuses each include the power consumption calculating unit, the feature calculating unit and the detecting unit according to claim 6; and
the power consumption calculating apparatus includes the model generating unit and the power consumption estimating unit; and
the power consumption calculating apparatus is configured to:
collect data concerning a value of the power consumption, the feature, and the starting time and the ending time of each device from the electrical apparatuses;
generate the model commonly for devices of a same device type in the homes, using the data collected, for each of device types;
calculate power consumption of each device in the homes, based on the data collected and the model of each device type; and
transmit a value of the power consumption of each device in the homes to the electrical apparatuses.
